(19) United States
(12) Patent Application Publication
(10) Pub. No.: US 2012/0025898 A1
(43) Pub. Date: Feb. 2, 2012

(54) Circuit Device

(75) Inventor: Tse-Peng Chen, Taipei (TW)

(73) Assignee: RICHWAVE TECHNOLOGY CORP., Taipei (TW)

(21) Appl. No.: 12/900,221

(22) Filed: Oct. 7, 2010

(30) Foreign Application Priority Data
Jul. 30, 2010 (TW) 99125307

(51) Int. Cl. H03K 17/00

(52) U.S. Cl. 327/524

(57) ABSTRACT

A circuit device includes an option pad, a first power source pad, and a first ground pad, wherein the option pad, the first power source pad, and the first ground pad are formed over various portions of a top surface of the circuit device, and a function of the circuit device is determined by coupling the option pad with one of the first power source pad and the first ground pad through a wire bond.

### CROSS REFERENCE TO RELATED APPLICATIONS

This Application claims priority of Taiwan Patent Application No. 99125307, filed on Jul. 30, 2010, the entirety of which is incorporated by reference herein.

### BACKGROUND OF THE INVENTION

1. Field of the Invention

The present invention relates to integrated circuit fabrication, and in particular relates to a circuit device with bonding-option structures.

2. Description of the Related Art

In the design of an integrated circuit (IC), a bonding option structure is usually provided for the IC so as to selectively alter an aspect of the hardware configuration in the IC. Thus, various aspects of hardware configuration in a circuit chip of an integrated circuit such as internal logic functions, specific functions, and clocking functions thereof can be selectively altered by manufacturers according to various application needs; thereby providing integrated circuit devices with similar hardware structures having multiple options.

One of the conventional bonding option structures is a power/ground bonding option structure. In FIG. 1, a conventional integrated circuit (IC) device 300 using a power/ground bonding option structure is illustrated.

As shown in FIG. 1, a top view of the IC device 300 is illustrated. The IC device 300 comprises a package substrate 100 and a circuit device 200 disposed over a portion of the package substrate 100. Herein, the circuit device 200 can be disposed over the package substrate 100 by packaging techniques such as a surface mounting technology (SMT).

In one embodiment, the circuit device 200 can be a semiconductor chip fabricated from a silicon wafer, and a plurality of bonding pads 202, 204, 206, 208, 210, 212, 214, 216, 218, 220, 222, 224, 226, 228, and 230 are separately disposed over various portions of a top surface of the circuit device 200 around an edge thereof. In one embodiment, the package substrate 100 can be formed of, for example, ceramic substrates or printed circuit boards (PCBs), and a plurality of bonding elements 102₁, 102₂, 104₁, 104₂, 106, 108, 110, 112, 114, 116, 118, 120, 122, 124, 126, and 128 can be disposed on various portions over a top surface of the package substrate 100 around an edge thereof.

In FIG. 1, the bonding elements 102₁, 102₂, 104₁, 104₂, 106, 108, 110, 112, 114, 116, 118, 120, 122, 124, 126, and 128 are illustrated as conductive bonding pads, but are not limited thereto, and the bonding elements can be also provided as other configurations such as leads or pins.

Still referring to FIG. 1, the bonding elements 106, 108, 110, 112, 114, 116, 118, 120, 122, 124, 126, and 128 disposed over the packaging substrate 100 may be used for functional circuit elements such as input/output, control, or clocking elements, and the bonding elements 102₁ and 102₂ may be used as power source elements, and the bonding elements 104₁, 104₂ may be used as ground elements. The bonding pads 202 and 204 formed over the top surface of the circuit device 200 may function as a power source pad and a ground pad, respectively, and are electrically connected to the bonding element 102₁ as a power source element and the bonding element 104₁ as a ground element. The bonding pad 206 may function as an option pad and is coupled to the bonding structure 102₂ which also functions as a power source element by a wire 400 or is coupled to the bonding structure 104₂ which also functions as a ground element by a wire 400′ (illustrated in dotted lines); thereby allowing related circuit functions such as internal logic functions, specific functions, or clocking functions in the circuit device 200 of the IC device 300 to be assigned. The other bonding pads 208, 210, 212, 214, 216, 218, 220, 222, 224, 226, 228, and 230 disposed over the top surface of the circuit device 200 may provided for other functional circuit pads such as input/output, control, and clocking pads and can be respectively coupled to one of the bonding elements 106, 108, 110, 112, 114, 116, 118, 120, 122, 124, 126, and 128 disposed over the packaging substrate 100 by wire bond methods; thereby providing electrical connections between the circuit device 200 and the packaging substrate 100.

As shown in FIG. 1, although the two possible coupling configurations between the option pad 206 and the bonding element 102₁ functioning as a power source element or the bonding element 104₁ functioning as a ground element can be used for assigning related circuit functions such as internal logic functions, specific functions, and clocking functions of the circuit device 200 such that the IC device 300 is provided with two different functions. The bonding elements 102₂ and 104₂, however, are additional power source and ground bonding elements formed over the packaging substrate 100; thereby requiring increased surface area of the packaging substrate 100 since the bonding elements are additionally formed over the packaging substrate 100. In addition, formations of the bonding elements 102₂ and 104₂ may occupy areas where other functional circuit elements may be formed; thereby decreasing amounts of bonding elements for electrically connecting the functional circuit bonding pads formed over the circuit device 200.

The above power/ground bonding elements used in the IC device 300 are unfavorable for size reduction of the package substrate 100 therein and positions of the bonding elements formed thereon may be thus occupied.

### BRIEF SUMMARY OF THE INVENTION

Therefore, an improved power/ground bonding option structure is needed for mitigating the above problems found in the conventional power/ground bonding option structures.

Circuit devices with improved circuit/ground bonding option pads capable of mitigating the above mentioned problems are provided.

An exemplary circuit device comprises an option pad, a first power source pad, and a first ground pad, wherein the option pad, the first power source pad, and the first ground pad are formed over various portions of a top surface of the circuit device, and a function of the circuit device is determined by coupling the option pad with one of the first power source pad and the first ground pad through a wire bond.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic diagram showing a conventional integrated circuit device having a bonding option structure;

FIG. 2 is a schematic diagram showing an integrated circuit device having a bonding option structure according to an embodiment of the invention; and

FIG. 3 is a schematic diagram showing an integrated circuit device having a bonding option structure according to another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

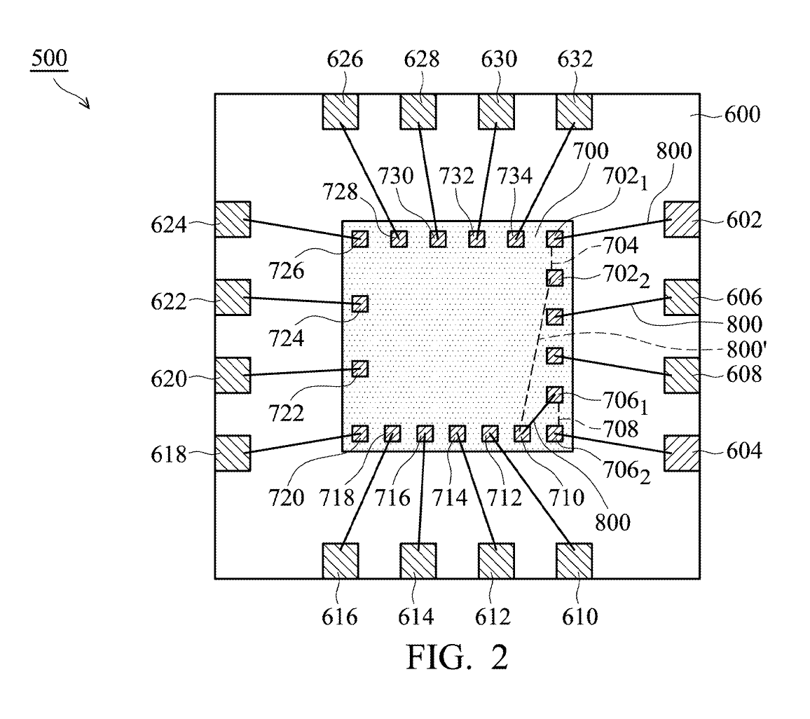

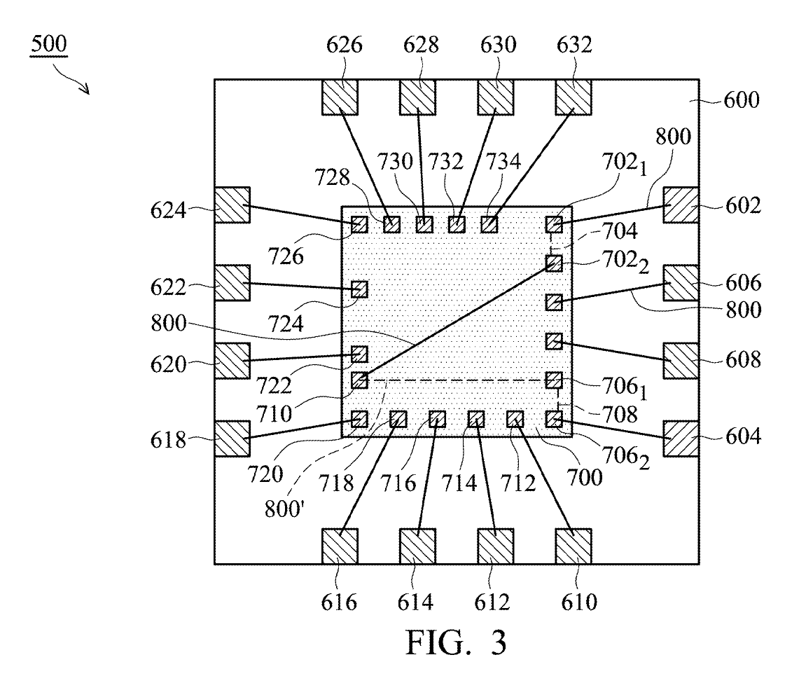

FIGS. 2-3 are schematic diagrams showing exemplary embodiments of the invention. In the figures, the same references represent the same elements.

In FIG. 2, an integrated circuit (IC) device 500 using a power/ground bonding option structure according to an embodiment of the invention is illustrated.

As shown in FIG. 2, a top view of the IC device 500 is illustrated. The IC device 500 comprises a package substrate 600 and a circuit device 700 disposed over a portion of the package substrate 600. Herein, the circuit device 700 can be disposed over the package substrate 600 by packaging techniques such as a surface mounting technology (SMT) packaging technique.

In one embodiment, the circuit device 700 can be a semiconductor chip fabricated from a silicon wafer, and a plurality of bonding pads 702₁, 702₂, 706₁, 706₂, 710, 712, 714, 716, 718, 720, 722, 724, 726, 728, 730, 732, and 734 are separately disposed over various portions of a top surface of the circuit device 700 around an edge thereof. In one embodiment, the package substrate 600 can be formed of, for example, ceramic substrates or printed circuit boards (PCBs), and a plurality of bonding elements 602, 604, 606, 608, 610, 612, 614, 616, 618, 620, 622, 624, 626, 628, 630, and 632 can be disposed on various portions over a top surface of the package substrate 600 around an edge thereof.

In FIG. 2, the bonding elements 602, 604, 606, 608, 610, 612, 614, 616, 618, 620, 622, 624, 626, 628, 630, and 632 are illustrated as conductive bonding pads, but are not limited thereto, and the bonding elements can be also provided as other configurations such as leads or pins.

Still referring to FIG. 2, the bonding elements 602, 604, 606, 608, 610, 612, 614, 616, 618, 620, 622, 624, 626, 628, 630, and 632 disposed over the packaging substrate 600 may be used as functional circuit elements such as input/output, control, or clocking elements, and the bonding element 602 may be used as a power source element, and the bonding elements 604 may be used as a ground element. The bonding pads 702₁ and 702₂ formed over various portions of the top surface of the circuit device 700 may function as power source pads, and the bonding pads 702₁ and 702₂ are electrically connected by a power source bus line 704 (illustrated as dotted lines) disposed in the circuit device 700. The bonding pads 706₁ and 706₂ formed over various portions of the top surface of the circuit device 700 may function as ground pads, and the bonding pads 706₁ and 706₂ are electrically connected by a ground bus line 708 (illustrated as dotted lines) disposed in the circuit device 700. One of the bonding pads 702₁ and 702₂ and one of the bonding pads 706₁ and 706₂ are coupled to the bonding element 602 as a power source element and the bonding element 604 as a ground element, respectively. The bonding pad 710 disposed over the circuit device 700 may function as an option pad and is coupled to one of the bonding pads 702₁ and 702₂ which function as a power source bonding pads by a wire 800 or one of the bonding pads 706₁ and 706₂ which function as a ground bonding pad by a wire 800′ (illustrated in dotted lines); thereby allowing related circuit functions such as internal logic functions, specific functions, or clocking functions in the circuit device 700 of the IC device 500 to be assigned. It is noted that the wire 800 coupled to the power source element or the ground element over the package substrate is not formed over the power source pad or the ground pad coupled to the bonding pad 710 which functions as the bonding option pad. The other bonding pads 712, 714, 716, 718, 720, 722, 724, 726, 728, 730, 732 and 734 disposed over the top surface of the circuit device 700 may provide for other functional circuit pads such as input/output, control, and clocking pads and can be respectively coupled to one of the bonding elements 610, 612, 614, 616, 618, 620, 622, 624, 626, 628, 630 and 632 disposed over the packaging substrate 600 by wire bonds; thereby providing electrical connections between the circuit device 700 and the packaging substrate 600.

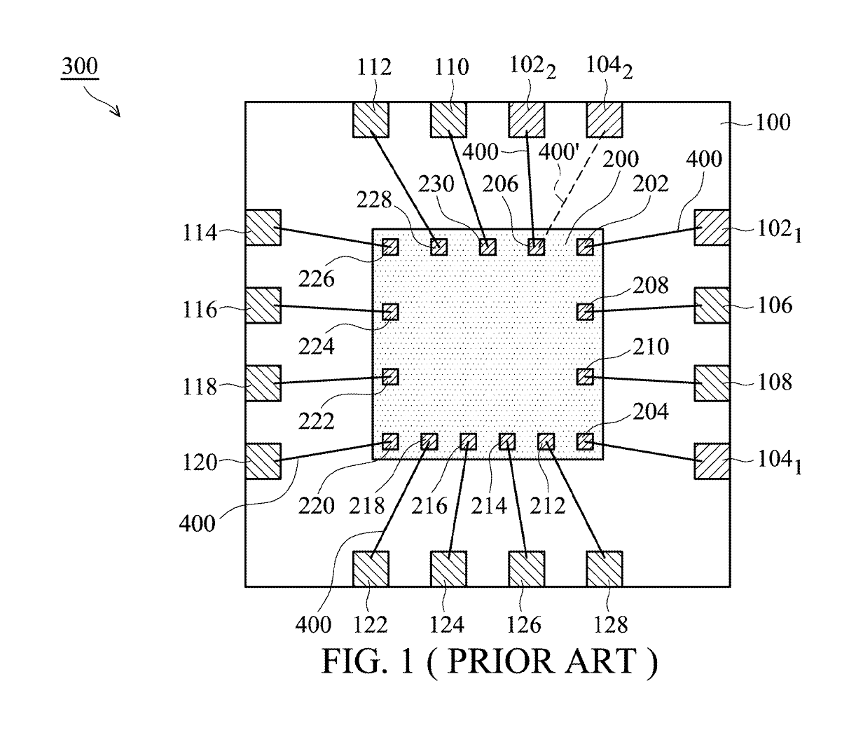

As shown in FIG. 2, though the electrically connected two power source pads (e.g. the bonding pads 702₁ and 702₂) and the two ground pads (e.g. the bond pads 706₁ and 706₂), and through the two possible coupling configurations between the bonding option pad 710 and one of the bonding pads 702₁ and 702₂ functioning as a power source pad and one of the bonding pad 706₁ and 706₂ functioning as a ground pad, related circuit functions such as internal logic functions, specific functions, and clocking functions of the circuit device 700 can be assigned such that the IC device 500 is provided with two different functions. Thus, there is no need to additionally provide the bonding elements 102₂ and 104₂ functioning as power source and ground elements of the integrated circuit device 300 shown in FIG. 1 over the package substrate 600, saving usable areas over the package substrate 600 and increasing the bonding pads for functional circuit pads over the package substrate 600 for adequately utilizing surface areas over the package substrate 600. In addition, through the connections of the bonding pad 710, functioning as ? option pads as shown in FIG. 2, amounts of the bonding pads 712, 714, 716, 718, 720, 722, 724, 726, 728, 730, 732 and 734 can be decreased according size reduction demand of the circuit device 700, and amounts of the bonding elements 610, 612, 614, 616, 618, 620, 622, 624, 626, 628, 630 and 632 over the package substrate 600 can be correspondingly decreased such that size of the IC device 500 is reduced. Thus, usage of the power/ground bonding option structure of the IC device 500 shown in FIG. 2 is advantageous for size reduction of the circuit device 700 and the package substrate 600.

In FIG. 2, the option pad 710 is illustrated as being adjacent to a side of the bonding pad 706₂ functioning as a ground pad but is not limited thereto. In another embodiment, the option pad 710 can be also disposed at different locations such as at a place between the bonding pads 720 and 722, as shown in FIG. 3.

In the exemplary embodiments shown in FIGS. 2 and 3, the bonding pads 702₁ and 702₂ are not limited to being power source pads and may function as ground pads while the bonding element 602 over the package substrate 600 functions as a ground element. Similarly, in the exemplary embodiments shown in FIGS. 2 and 3, the bonding pads 7026₁ and 706₂ are not limited to functioning as ground pads and may function as power source pads while the bonding element 604 over the package substrate 600 functions as a power source element. Functions of the above elements can be properly adjusted according to practical applications.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A circuit device, comprising
an option pad;
a first power source pad; and
a first ground pad, wherein the option pad, the first power source pad, and the first ground pad are formed over various portions of a top surface of the circuit device, and a function of the circuit device is determined by coupling the option pad with one of the first power source pad and the first ground pad through a wire bond.

2. The circuit device as claimed in claim 1, further comprising a plurality of functional circuit pads separately disposed over various portions of the top surface of the circuit device, wherein the functional circuit pads are formed over various portions of the circuit device around an edge thereof, and the function circuit pads are formed at locations different from that of the option pad, the first power source pad, and the first ground pad.

3. The circuit device as claimed in claim 1, further comprising a second power source pad formed over a portion of the top surface of the circuit device and adjacent to the first power source pad.

4. The circuit device as claimed in claim 3, further comprising a first power bus line disposed in the circuit device to electrically connect the first power source pad to the second power source pad.

5. The circuit device as claimed in claim 1, further comprising a second ground pad disposed over a portion of the top surface of the circuit device and adjacent to the first ground pad.

6. The circuit device as claimed in claim 1, further comprising a first ground bus line disposed in the circuit device to electrically connect the first ground pad to the second ground pad.
